(19) United States
(12) Patent Application Publication
(10) Pub. No.: US 2026/0050020 A1
(43) Pub. Date: Feb. 19, 2026

(54) DEVICE FOR MEASURING THE POWER DENSITY AND TOTAL ENERGY DENSITY OF NON-IONIZING ELECTROMAGNETIC RADIATION

(71) Applicant: ALEXANDER S. DMITRIEV, Moscow (RU)

(72) Inventors: ALEXANDER S. DMITRIEV, Moscow (RU); VADIM V. ITSKOV, Moscow (RU); VADIM A. LAZAREV, Dolgoprudny (RU); ANTON I. RYZHOV, Moscow (RU); ANTON V. UVAROV, Dolgoprudny (RU)

(21) Appl. No.: 19/102,192

(22) PCT Filed: Oct. 17, 2023
(86) PCT No.: PCT/RU2023/050245

§ 371 Date: Feb. 7, 2025

(30) Foreign Application Priority Data
Aug. 12, 2022 (RU) 2022132104

(51) Int. Cl. G01R 29/08; G08B 7/06

(52) U.S. Cl. CPC G01R 29/0871; G01R 29/0857; G01R 29/0878; G08B 7/06

(57) ABSTRACT

The invention is classified as measuring equipment, particularly for measurement of the power density of non-ionizing electromagnetic radiation and the total energy density. The device includes planar antenna and detection unit. Therewith, the detection unit is built in the receiving surface of the planar antenna, and it interacts with the antenna through the high-frequency fields and currents, while the detection unit with the antenna create unified electrodynamic receiving structure. The technical result is to ensure the minimum mismatch of antenna and detector in the upper frequency range while preserving the possibility to measure the power density of non-ionizing electromagnetic radiation and the total energy density in the hyper-broadband range.

### TECHNICAL FIELD

The invention is classified as measuring equipment, particularly for measurement of the power density of non-ionizing electromagnetic radiation and the total energy density.

### BACKGROUND

In the prior art, a known electromagnetic radiation monitor is disclosed in U.S. Pat. No. 3,783,448 A document (published on Jan. 1, 1974). The device for measurement of total electromagnetic radiation and non-ionizing electromagnetic radiation impact consists of: polarization-insensitive antenna; crystal rectifier; and integrator that has anode, cathode and electrolytic gap between anode and cathode. The crystal rectifier output signal applied to anode and cathode causes migration of electrolyte ions through the electrolytic gap to the anode, proportional to a charge that passes from the rectifier, to sum up the amount of radiation to which the antenna is subject within the entire time period. Therewith the antenna is directly connected to the detector on the crystal rectifier that is directly connected to the integrator.

The disadvantages of this radiation monitor is impossibility to accumulate data for a long-term measurement period, small measurement range, and absence of independent power supply source.

In the prior art, a known system of electromagnetic contamination measurement is disclosed in DE 29810794 U1 document (published on Nov. 26, 1998). The radiation monitor consists of a small pocket-size plastic body in which printed circuit board, antenna, precision voltage divider, instrumentation amplifier, rectifier bridge and filter are installed. Electromagnetic field induces alternating voltage in the antenna, which is supplied directly to the rectifier bridge. Symmetrically rectified voltage passes through the filter that removes residual alternating voltage, and to the instrumentation amplifier where voltage is increased.

The disadvantages of this radiation monitor are also the impossibility to accumulate data for a long-term measurement period and a small measurement range.

In the prior art, a known device for environmental monitoring of harmful UHF radiation impact of a mobile phone on a human organism is disclosed in RU 65241 U1 document (published on Jul. 27, 2007). The device includes receiving antenna, UHF radiation detector, UHF radiation level measurement unit, controller made as a microprocessor with a possibility to set a sanitary standard, and sanitary standard exceedance indication unit, all connected in series. In addition, the device includes UHF radiation duration measurement unit installed between the UHF radiation detector output and corresponding controller input, therewith the latter has a feature of determining the dose of harmful UHF radiation impact on a human organism accumulated over time based on output signals of UHF radiation level and duration measurement units, and comparing it with a sanitary standard.

The disadvantages of this radiation monitor are also the impossibility to accumulate data for a long-term measurement period and a small measurement range.

In terms of the technical nature, the most similar to the declared radiation monitor is the device disclosed in MICROWAVE ELECTROMAGNETIC DOSIMETRY OF INDIVIDUAL ECOLOGICAL SPACE document prepared by A. S. Dmitriev, V. V. Itskov, A. I. Ryzhov, and A. V. Uvarov, published in INSTRUMENTATION ENGINEERING PHYSICS magazine (2020, vol. 9. No. 1 (35)). This device was chosen as a prototype of the declared solution.

The above-mentioned device includes antenna, detector, microcontroller, AD converter, built-in memory, real time clock, USB interface, FLASH memory, USB port, controlled surge protector, power supply driver and battery. Therewith the antenna is made as printed monopole, integrally packaged with the radio emission detector.

However, the antenna in the above-mentioned radiation monitor weakly matches the radiation detector within the upper frequency measurement range.

This device for continuous long-term measurement of the power density of non-ionizing electromagnetic radiation and the total energy density is designed to eliminate the prototype's disadvantages.

The technical result is to ensure the minimum mismatch of antenna and detector in the upper frequency range while preserving the possibility to measure the power density of non-ionizing electromagnetic radiation and the total energy density in the hyper-broadband range.

The device for long-term continuous measurement of the power density of non-ionizing electromagnetic radiation and the total energy density in a predetermined frequency band that contains a planar antenna and a detection unit is characterized in that the detection unit is built into the receiving surface of the planar antenna, and it interacts with the antenna through high-frequency fields and currents, while the detection unit and antenna form a unified electrodynamic receiving structure.

Integration of the planar antenna and the detection unit into the unified electrodynamic receiving structure by building the detection unit in the antenna receiving surface allows for minimization of mismatch of the antenna and the detection unit in the upper frequency measurement range.

### BRIEF DESCRIPTION OF DRAWINGS

FIG. 1 is a block diagram of a radiation monitor.

### DETAILED DESCRIPTION

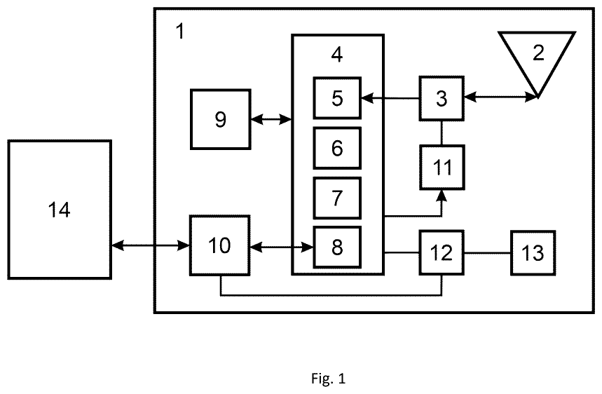

FIG. 1 designates the following: 1—radiation monitor, 2—antenna, 3—detection unit, 4—data processing and displaying unit, 5—AD converter, 6—built-in memory, 7—real time clock, 8—USB interface, 9—FLASH memory, 10—USB port, 11—controlled surge protector, 12—power supply driver, 13—independent power supply source, 14—readout unit.

The personal radiation monitor 1 includes body, non-directional antenna 2 able to work in hyper-broadband mode, detection unit 3, data processing and displaying unit 4, independent power supply source 13 and power supply driver 12. The data processing and displaying unit can be made on the basis of a microcontroller to which the data storage media in the form of additional FLASH memory 9 and micro-USB port 10 is connected for storage of processed data and interface with the readout unit 14.

The microcontroller contains analogue-digital converter (ADC) 5, built-in memory 6, real time clock 7 and USB interface 8 with port 10 operating as a unit for communication with external current sources, computing and communication devices. The body is additionally equipped with a state of charge indicator for independent power supply source 13.

The antenna in one design is made as hyper-broadband dipole printed antenna. The antenna in another design can be made as hyper-broadband monopole printed antenna.

The antenna can be also made as hyper-broadband F-shaped printed antenna.

The detection unit is made with a possibility to amplify, detect and filter the above-mentioned high-frequency current into single-pole output signal that is a monotonic function of the received electromagnetic radiation.

The detection unit in one design is made as logarithmic amplifier and low frequency filter in series.

The detection unit in another design is made as quadrature detector, amplifier and low frequency filter in series.

The data processing and displaying unit is made with a possibility to output the accumulated data upon request for any time interval, both in the form of currently received power, and in the form of total energy accumulated within the above-mentioned range, and also to preset the device software in accordance with the chosen operation conditions.

The body can also include light or acoustic indicator for immediate warning the user about a radiation level.

### Example of the Device Implementation

The basis of the radiation monitor is a hyper-broadband receiver with operating frequency band of 800 to 8,000 MHz (upper to lower operation frequency ratio 10:1), dynamic range of 55 dB and sensitivity about 3 nW. The operation frequency range of the receiver covers nearly the entire used and prospective (classified as 5G up to 6 GHz) frequency range of operation of the modern mobile communication systems, except for the frequency range below 800 MHZ that is rarely used now.

The receiver consists of printed antenna, with detection unit built-in inside the receiving surface. The resulted electrodynamic receiving structure allows for measuring the electromagnetic field strength in all directions and in hyper-broadband mode, and it has the minimum mismatch of the antenna and the detector in the upper frequency range.

The hyper-broadband receiver measures the strength of electromagnetic microwave signal incoming to the antenna once per second and records it to the memory. This data can be directly displayed on the screen of the computer (laptop, tablet, smartphone) connected to the radiation monitor, and then there is a possibility to observe dynamics of the incoming signal strength variability in real time. After accumulation of counts within 1 minute, the total energy is recorded to the persistent storage, and this data can be recorded within a long period of time. The maximum record time is more than 6 months. This data or any of its fragments can be also displayed on the monitor in the form of graphs.

The radiation monitor is connected to computer, tablet or smartphone through USB-interface. It is also used for the battery charging from the external computing device or from 220 V mains.

Each copy of the personal radiation monitor has a unique number. The possibility to set and read out the individual number of each personal radiation monitor is implemented, which allows for processing the data of multiple radiation monitors on one readout unit (PC, tablet, smartphone), and storing personal statistics remotely for many devices, for example, in a cloud. The device is provided with synchronization of calendar and current time with the readout unit when connected through USB interface to match the obtained radiation dose with the absolute time.

The device works as follows:

During the first power supply, or regular wakeup, the settings controller is started up, where input-output ports can be configured. Then, a check for availability of external power supply is carried out, and in case of positive result, the internal high-speed timing source is started up for USB initialization. In case of absence of external power supply, the slower yet more power-saving internal multi-speed generator is started up, and the device is switched to independent operation mode. If it is the first start-up, the device initiates the external tuning fork and the real time clock. In case of independent operation, ADC is started up at this moment, which is displayed by switching on the green LED on the side panel of the device. Then the device is in standby mode.

In case of interruption of completion of data receipt on ADC, which is displayed by switching off the green LED on the side panel of the device, this data is processed and summed up with previous values. Then the internal counter is checked. New information about the address identifier of the latest data in FLASH memory is recorded in the microcontroller registers, where this data is stored securely when the device is in sleeping mode.

If the timer interruption is actuated, ADC is started up, which is displayed by switching on the green LED on the side panel of the device, and availability of external power supply is checked. In case of absence of external power supply, the device is switched to independent operation mode and standby mode. If external power supply is available, the device is immediately switched to standby mode.

If the data from the readout unit is obtained through USB interface, the personal radiation monitor processes it, and depending on the request, creates the response data message. During communication session, it is possible to set an individual number of the personal radiation monitor, synchronize absolute time, read out random fragment of the device memory, read and record an identifier, delete pages in FLASH memory, using a specialized software on the read-out unit. After the session, the personal radiation monitor is switched to standby mode.

1. A device for long-term continuous measurement of power density of non-ionizing electromagnetic radiation and total energy density in a predetermined frequency band, the device including planar antenna and a detection unit, wherein the detection unit is built into a receiving surface of the planar antenna, and wherein the detection unit interacts with the planar antenna through high-frequency fields and currents, and wherein the detection unit and the planar antenna form a unified electrodynamic receiving structure.

2. The device of claim 1, wherein the planar antenna is made as a hyper-broadband dipole printed antenna.

3. The device of claim 1, wherein the planar antenna is made as a hyper-broadband monopole printed antenna.

4. The device wherein the planar antenna is made as a hyper-broadband F-shaped printed antenna.

5. The device of claim 1, wherein the detection unit is configured to amplify, detect and filter the high-frequency currents into a single-pole output signal that is a monotonic function of the received non-ionizing electromagnetic radiation.

6. The device of claim 1, wherein the detection unit is made as logarithmic amplifier and low frequency filter in series.

7. The device of claim 1, wherein the detection unit is made as a quadrature detector, amplifier and low frequency filter in series.

8. The device of claim 1, further including a data processing and displaying unit.

9. The device of claim 8, wherein the data processing and displaying unit is configured to output accumulated data upon request for any time interval, both in a form of currently received power, and in a form of the total energy accumulated within a predefined range, and wherein the data processing and displaying unit is configured to preset software settings for the device in accordance with predefined operation conditions.

10. The device of claim 8, further including a light or acoustic indicator for immediate warning to a user about a radiation level.

11. The device of claim 1, further including data storage media.

12. The device of claim 1, further including a unit for communication with external current sources, computing and communication devices.

13. The device of claim 1, further including an independent power supply source.
